(19) United States
(12) Patent Application Publication
(10) Pub. No.: US 2011/0175623 A1
(43) Pub. Date: Jul. 21, 2011

(54) Online Incipient Fault Sensor Device for Detection of Incipient Fault in Oil-Filled Electrical Apparatus Such as a Transformer

(75) Inventors: Vagish Shrinet, Vadodara (IN); Nilesh Pandya, Vadodara (IN)

(73) Assignee: ELECTRICAL RESEARCH & DEVELOPMENT ASSOCIATION, Makarpura, Vadodara (IN)

(21) Appl. No.: 12/994,067

(22) PCT Filed: Nov. 18, 2009
(86) PCT No.: PCT/IN09/00647

§ 371 Date: Mar. 16, 2011

(30) Foreign Application Priority Data
Mar. 23, 2009 (IN) 659/MUM/09

(51) Int. Cl. G01R 31/02

(52) U.S. Cl. 324/537

(57) ABSTRACT

A sensor detecting incipient fault in oil-filled electrical apparatuses (transformer) includes a sensor head (1) directly mounted on an air vent port of a Buchholz relay (3) and a display/control unit (2) operably connected to the sensor head (1). The sensor head (1) senses hydrogen gas and transmits to the display/control unit (2) an electrical signal equivalent to the concentration of the free hydrogen accumulated in the Buchholz relay (3). The display/control unit (2) compares the value of the electrical signal equivalent with a stored value and outputs a signal when the received signal value exceeds a preset value. The sensor head (1) comprises a membrane (10,11) formed of a first (ceramic) material (10) to isolate free gases from the liquid phase to the gaseous phase, and a second (polymeric) material (11) to isolate hydrogen from the mixed gaseous phase.

An improved online incipient fault sensor device for detection of incipient fault in oil-filled electrical apparatus such as a transformer.

### FIELD OF INVENTION

The present invention generally relates to detection of incipient fault developed in electrical equipment. More particularly, the invention relates to an improved online incipient fault sensor device for detection of incipient fault in oil-filled electrical apparatus such as power transformers during operation.

### BACKGROUND OF INVENTION

In an electrical network of generation, transmission and utilization, a transformer is one of the key and costliest equipment. For reliable and economical power supply, it is essential that it functions at the optimal level throughout the designed life span and hence it draws a special attention to monitor its good health during service. The importance of the costly power transformer becomes more significant because it is expensive to afford a standby transformer. To protect the transformer and thereby the whole system from premature failure, different devices are provided. The fault condition is supposed to be detected by the protection system and isolate the transformer from the main stream as early as possible to avoid further damage to the transformer as well as the system. A forced shutdown of power network results in a huge loss of revenue, which is not desirable and affordable.

Condition monitoring is a necessity for key equipment like transformer in electrical network for improved reliability. Sensing a fault at its initial stage helps utility to take remedial action well in time to avoid any premature failure. In electrical systems, a transformer is one of the key equipment and hence it is safeguarded through a various protective devices. Over and above, these devices, various condition-monitoring techniques like Dielectric Dissipation factor, Partial Discharge measurement, Dissolve Gas Analysis (DGA) etc. are adapted to detect development of any incipient fault in the transformer during the service.

Among these protective systems, DGA is a reliable and well-proven technique. In the DGA, at regular intervals, say annually, a small quantity (200 ml) of transformer oil is collected from the transformer main tank and carried to a laboratory for analysis. The concentrations of different dissolved gasses are determined with the help of gas chromatography. By evaluating the rate of rise in gas concentration between the successive DGAs as well as the concentration of individual gases; the presence of fault, its type and severity are assessed. There are several instances where DGA played a key role in saving the transformer from catastrophic failure.

DGA although reliable but is an OFFLINE technique. The status of fault developed between two successive analyses can not be detected. In addition, an improper sampling may lead to erroneous results.

A conventional gas operated Buchholz relay; which became an integral part of the transformer from last so many years, is online and cheaper too. It operates in both types of fault i.e. thermal and electrical. But it has been experienced that it is slow, detects the fault at a later stage and not sensitive to low intensity fault. The Buchholz relay is mounted on top of the main tank between the conservator and the main tank. Thus, in case of any thermal/electrical fault, gases evolved and collected in Buchholz relay. When gases accumulated on the Buchholz relay crosses a preset value, the relay operates and gives an alarm. It is often found that by the time Buchholz relay operates, a considerable damage to the transformer is already occurred. Accordingly, it is desirable to isolate the faulty transformer from the main system as early as possible to avoid any further damage to the transformer be isolated as well as to the system.

Indian patent no 204691 granted to the inventors of present disclosure which is herein incorporated by way reference which discloses an online incipient fault sensor for oil-filled transformer. The present invention constitutes an improvement which achieves higher accuracy and provide faster detection.

### OBJECTS OF INVENTION

It is therefore an object of the invention to propose an improved online incipient fault sensor device for detection of incipient fault in an oil-filled electrical apparatus.

Another object of the invention is to propose an improved online incipient fault sensor device for detection of incipient fault in oil-filled electrical apparatuses, which is capable to detect both thermal and electrical fault at the initial stage to allow immediate remedial action which saves the electrical apparatuses form any major damage.

A further object of the invention is to propose an improved online incipient fault sensor device for detection, which is reliable sensitive, and fast to detect the incipient faults in the electrical apparatus.

A still further object of the invention is to propose an improved online incipient fault sensor device for detection of incipient fault in electrical apparatuses, which additionally acts as a condition monitoring tool for the electrical apparatuses.

Yet another object of the invention is to propose an improved online incipient fault sensor device for detection of incipient fault in electrical apparatuses, which adapts a membrane consisting of dual materials namely ceramic and polymeric, the former type of material isolating free gases from liquid phase to gas phase, and the later type of material isolating hydrogen from the mixed gaseous phase, thereby improving the sensing accuracy.

Yet further object of the invention is to propose an improved online incipient fault sensor device for detection of incipient faults in electrical apparatuses, which is cost-effective, easy to be installed, and provide accurate results.

### SUMMARY OF INVENTION

A detailed study conducted by the inventors reveals that the concentration of evolved (free) hydrogen accumulated in the buchholz relay is comparatively very high than that of the dissolved hydrogen. Based on this findings, a new concept of online sensing of evolved hydrogen has been conceived and a device has been designed, fabricated and thoroughly tested. It is be noted that hydrogen gas is produced in case of both electrical and thermal faults in a transformer. This factor coupled with least solubility of the hydrogen gas in transformer oil makes the inventive device efficient and technically advantageous.

The ONLINE FAULT SENSOR DEVICE of the invention detects the incipient fault in oil filled electrical apparatuses such as a power transformer during the service. This helps the user to take necessary remedial action on time at the initial stage of development of the fault to save the transformer from major damage, and thereby prevent power network system from the major damage. This device of the invention is online, simple, economical and gives indication of incipient fault development at its early stage.

The basic working principle of the device is to sense the free hydrogen gas evolved due to fault. In case of either type of fault namely thermal and electrical, developed any where inside the transformer tank, the hydrogen—a key gas, evolves very fast. The fault sensor senses the presence of hydrogen concentration and accordingly gives an alarm i.e. Green light (in case of normal working), Yellow light (in the event of development at the initial fault level), and Red light (in the event of development of higher fault level).

The fault sensor contains two part namely a sensor head and a control cum display unit. The sensor head can be directly mounted on an air vent port of the Buchholz relay without any modification to the transformer, while the control cum display unit can be mounted in a marshaling box near to the transformer. The sensor head detects the presence of hydrogen and send signals to the control unit where the signal is analyzed and corresponding alarm is given. The device is light in weight (about 0.5 kg each for sensor head and display unit), easy and quick to install, (<two hours), and having a meager power requirement (in mW) and economical.

In this sensing device, the evolved hydrogen gas is separated from the transformer oil by using a membrane having desired porosity and capable to withstand working environments (pressure up to 10 kg/cm²) and temperature (up to 200° C.). It is also compatible with oil. The separated hydrogen when comes into contact with the sensing element, a surface adsorption takes place and the electrical resistance changes accordingly. The change in the electrical resistance is converted into equivalent mV signals and carried to the display unit through a screened cable. The signal output is linear in the desired range. The sensor response is fast (<one minutes). The surface adsorption is a reversible phenomenon and therefore in the absence of hydrogen gas, the sensor regains its initial electrical resistance value. The life of the sensing element of the device is more than five years.

Based on the simulated fault study, the alarm levels are set for normal (Green), warning (Yellow) and fault (Red) conditions.

According to the inventive device, the evolved hydrogen is sensed which becomes advantageous because the hydrogen being a lighter gas tries to move upwards, hence concentration of the evolved gas is higher than the dissolved. Sensing large quantity of gas is easier and accurate.

### Advantages Over Other Known Alternatives

(i) Online measurement facility,
(ii) Cheaper,
(iii) Protection of costly transformer with an expenditure of small amount,
(iv) Sensitive and reliable,
(v) Quick and easy installation facility,
(vi) Easy replacement is possible,
(vii) Gives audio/visual alarm,
(viii) Response time: Less Than 2 minutes,
(ix) Display range: 0-1999,
(x) Accuracy: ±10%,
(xi) Repeatability: ±2%,
(xii) Size/Weight:
   (a)—Sensor head—50 mm diameter, 50 mm length (0.3 kg)
   (b)—Control cum display unit—95×100 mm (0.8 kg)
(xiii) Input power: 220V AC, <100 mA,
(xiv) Alarm: Low (Visual) and High (Audio),
(xv) No modification is required in the existing transformer to install the online fault sensor. The device can be directly mounted on the air vent port of the Buchholz relay in less than one-hour time.

### BRIEF DESCRIPTION OF THE ACCOMPANYING DRAWINGS

FIG. 1—shows a schematic diagram of an improved on-line incipient fault sensor device according to the invention.

FIG. 2—a pictorial view of the sensor head mounted on a Buchholz relay according to the invention.

FIG. 3—shows a pictorial view of the display cum control unit of the inventive device.

FIG. 4—shows a graphical representation of the inventive device for various possible faults.

FIG. 5—shows a constructional details of the device of the invention.

FIG. 6—shows an electronic circuit for sensing the pressure of hydrogen and display.

### DETAIL DESCRIPTION OF INVENTION

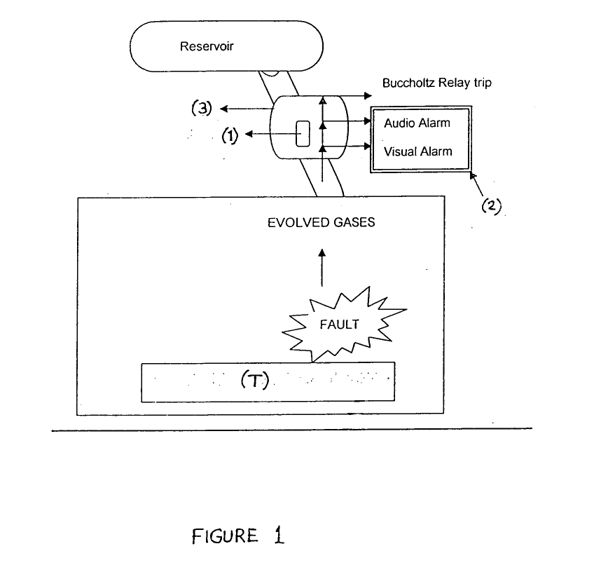

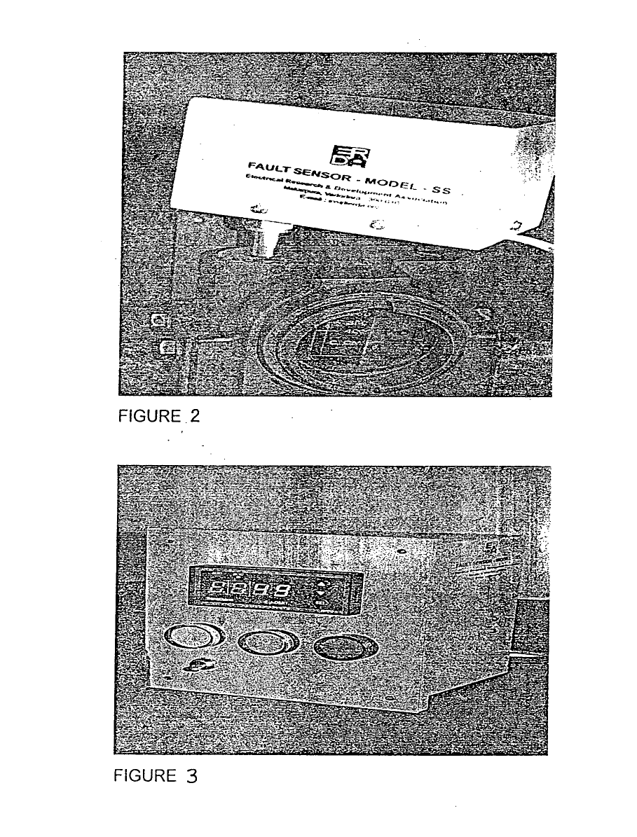

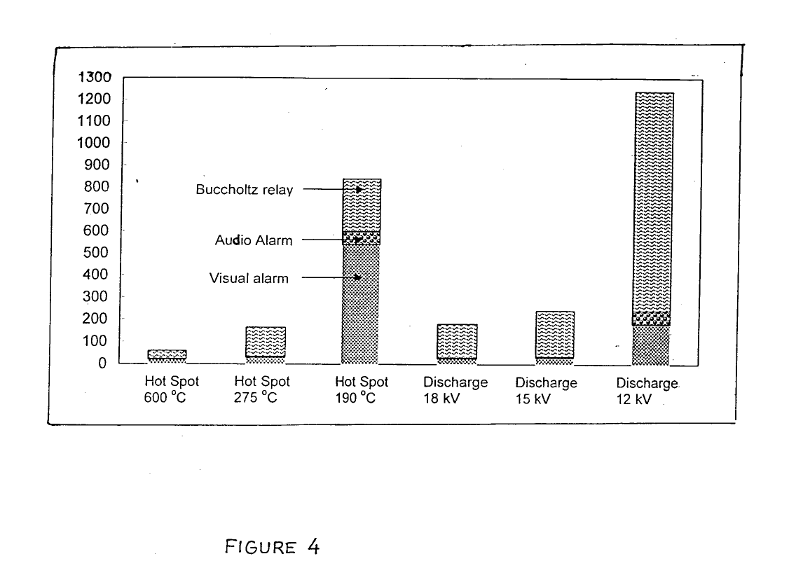

As shown in FIGS. 1, 5, and 6, the device basically has two components namely a Sensor Head (1) and a Display cum Control Unit (2). The sensor head consists of a sensing element (8), a ceramic-polymeric membrane (10, 11) to isolate the free hydrogen gas from the transformer oil. The sensor head (1) is directly mounted on an air vent port of a Buchholz relay (3).

When the hydrogen gas reaches to the sensor head (1), it senses and gives equivalent electrical signal, which is transmitted through a screened cable (12) to the display cum control unit (2). The display cum control unit (2), can be mounted in the marshaling box (not shown) near to the transformer (T) or control room of sub station. The display cum control unit (2) requires a 220 V, 50 Hz power supply. This unit (2) is provided for a display of relative concentration of free hydrogen at the Buchholz relay (3). When the signal crosses a present value, the display unit (2) gives a first visual alarm to alert the operator. In case the first alarm is not noticed and if the fault continues, the display unit (2) gives an audio alarm.

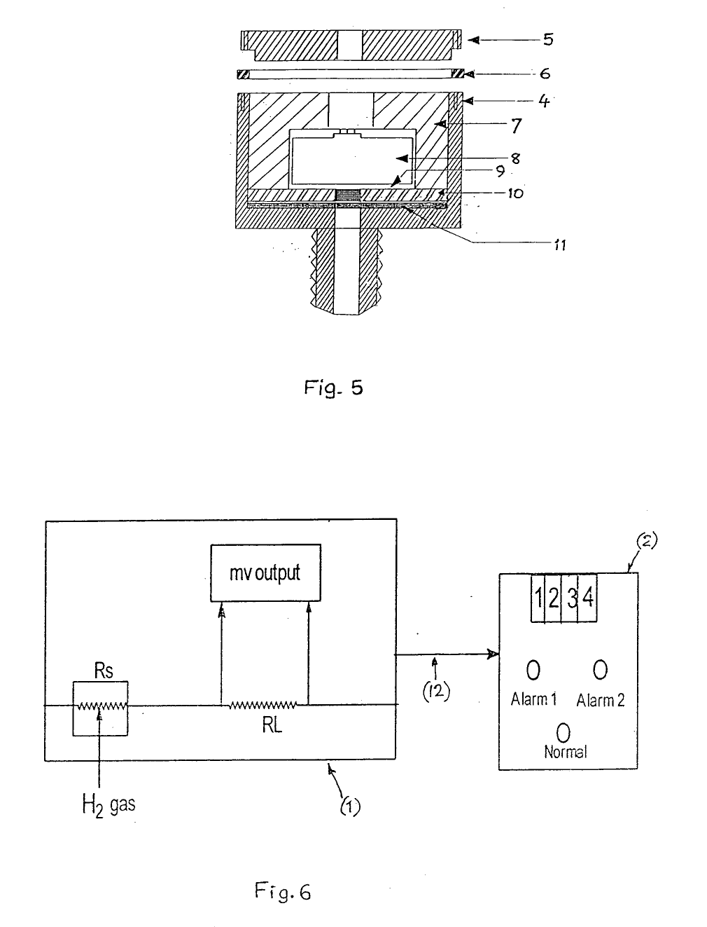

FIG. 5 shows constructional details of a sensor head (1). A sensing element (8) is a sensitive part of the device and therefore to protect it from atmospheric hazards like, water, dust, vibrations, electromagnetic interferences etc.; it is kept in a metallic housing (4). At one end through standard thread, the sensor head (1) can easily be mounted on to an air vent port of the Buchholz relay (3). In case of development of either type of thermal or electrical fault, the oil gets decomposed and hydrogen with other gases evolve. With the help of a ceramic membrane (10), gas is isolated from the oil and with the help of a polymeric membrane (11); only hydrogen is allow to pass through to the sensing element (8). The necessary ″O rings (9) and gasket (6) are provided to avoid any leakage and a soft filler (7) is provided to resist any vibration.

FIG. 6 shows equivalent circuitry for sensing the presence of hydrogen and display accordingly, Rs represent the surface resistance of the sensing element (8) and R_{L} represents the load resistance across which the equivalent voltage drop is measured. Change in the Rs, get reflected in equivalent change in voltage across the R_{L}.

The R_{L} is connected in series with the Rs and a regulated constant voltage is applied across the Rs+R_{L}. In normal condition, the Rs is having its initial surface resistance value. When hydrogen comes into contact with the Rs, a surface phenomenon takes place and the surface resistance decreases. This decreases the voltage drop across the Rs. As the Rs+R_{L} are supplied with constant voltage source, any decrease in voltage across the Rs increases the voltage across the R_{L} accordingly. This is similar in reverse phenomenon.

The mVolt output from the R_{L} is transferred to display cum control unit (2) through a screened cable (12). The Display unit (2) is provided with an electronic circuitry for signal converter from analog to digital to display the mV drop from the R_{L} in 0 to 3000 units. The current status of hydrogen is also displayed through LED i.e. Green for normal condition. Yellow for alarm 1 or low alarm or visual alarm and Red for alarm 2 or high alarm or audio alarm. The value of alarm 1 and alarm 2 can be preset and when the signal value increases beyond the set value, display will show equivalent alarm.

To evaluate the performance of the sensor device, a study has been conducted at a simulated thermal and electrical fault conditions. A rectangular metallic chamber was fabricated. A 25 mm standard Buchholz relay was mounted through a pipe on the top of the chamber. At the air vent port of the Buchholz relay, the inventive fault sensor device was mounted.

Hot spot as a thermal fault of three different magnitudes and similarly electrical fault of three different magnitudes were developed in the chamber by using electrodes. During the fault, the evolved gas concentration, the amount of free gas accumulated in the Buchholz relay and the sensor reading with time were measured. Concentration of the free hydrogen was measured using a gas chromatograph.

Table 1 shows the response time of Fault sensor in comparison with
conventional Buccholtz relay, which is graphically presented in Fig. 3.

| High Temperature Fault | | | High energy Discharge fault | | |
|---|---|---|---|---|---|
| 600° C. | 275° C. | 190° C. | 18 kV | 15 kV | 12 kV |
| 20 mins. | 30 mins. | 540 mins. | 25 mins. | 30 mins. | 180 mins. |
| 25 mins. | 35 mins. | 600 mins. | 30 mins. | 35 mins. | 240 mins |
| 60 mins. | 165 mins | 840 min | 180 mins. | 240 mins | 1040 mins |

1-2. (canceled)

3: An online incipient fault sensor device for detection of incipient fault in oil-filled electrical apparatuses such as a transformer, the device comprising:
a sensor head directly mounted on an air vent port of a Buchholz relay; and
a display cum control unit operably connected to the sensor head,
the sensor head operative for sensing the hydrogen gas and transmitting to the display cum control unit an electrical signal equivalent to the concentration of the free hydrogen accumulated in the Buchholz relay the display cum control unit comparing the signal value with a stored preset value, and outputting a first signal when the received signal value exceeds a preset value,
wherein the sensor head comprises a membrane formed of a combination of two types of materials, the first type being a ceramic material to isolate free gases from the liquid phase to the gaseous phase, and the second type being a polymeric material to isolate hydrogen from the mixed gaseous phase.

4: The online incipient fault sensor device for detection of incipient fault in oil-filled electrical apparatuses according to claim 3, further including outputting a second signal in response to the received signal value exceeding the preset value for a predetermined interval of time following the first signal being output.

5: The online incipient fault sensor device for detection of incipient fault in oil-filled electrical apparatuses according to claim 3, wherein a cable connects the sensor and the display cum control unit.

6: The online incipient fault sensor device for detection of incipient fault in oil-filled electrical apparatuses according to claim 3, wherein the sensor head comprises a sensing element that adsorbs the hydrogen gas and has a resistance that is based on the amount of adsorbed hydrogen gas.
